(19) United States
(12) Patent Application Publication
(10) Pub. No.: US 2025/0069960 A1
(43) Pub. Date: Feb. 27, 2025

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventor: Sunjae Kim, Suwon-si (KR)

(21) Appl. No.: 18/799,115

(22) Filed: Aug. 9, 2024

(30) Foreign Application Priority Data
Aug. 22, 2023 (KR) 10-2023-0109477

(51) Int. Cl. H01L 21/66; H01L 23/00; H01L 23/31; H01L 23/48; H01L 25/18; H10B 80/00

(52) U.S. Cl. CPC H01L 22/32; H01L 24/16; H01L 24/32; H01L 24/73; H01L 25/18; H01L 23/3107; H01L 23/481; H01L 24/14; H01L 2224/14181; H01L 2224/16146; H01L 2224/32013; H01L 2224/32145; H01L 2224/73204; H10B 80/00

(57) ABSTRACT

A semiconductor package includes a first semiconductor chip having a chip mounting region on a central portion thereof and a test region surrounding the chip mounting region; a plurality of first measurement structures on the test region and sequentially arranged to be spaced apart from an edge of the chip mounting region; a second semiconductor chip mounted on the chip mounting region of the first semiconductor chip via a plurality of conductive bumps; an adhesive layer filling a gap between the first semiconductor chip and the second semiconductor chip, and including a central portion in the chip mounting region and at least one overflow portion protruding from the central portion to the test region to contact at least one of the plurality of first measurement structures; and a molding member on the upper surface of the first semiconductor chip to cover side surfaces of the second semiconductor chip.

### PRIORITY STATEMENT

This application claims priority under 35 U.S.C. § 119 to Korean Patent Application No. 10-2023-0109477, filed on Aug. 22, 2023 in the Korean Intellectual Property Office (KIPO), the contents of which are herein incorporated by reference in their entirety.

### BACKGROUND

### 1. Field

Example embodiments relate to a semiconductor package and a method of manufacturing the semiconductor package. More particularly, example embodiments relate to a semiconductor package including a multi-chip package including a plurality of stacked chips and a manufacturing method thereof.

### 2. Description of the Related Art

A plurality of chips may be sequentially stacked using an adhesive film by a thermal compression bonding (TCB) process. In the thermal compression bonding process, the adhesive film such as a non-conductive film may be used to stably bond conductive bumps for connection between the chips. Since the thermal compression bonding process is performed under a high-temperature condition and a high-pressure condition, a portion of the non-conductive film between the chips may flow to be dispersed in an outer lateral direction during the TCB process. The portion of the non-conductive film exposed outside the chip may reduce a reliability of a final product. Accordingly, there is a need to sort products having the portion of the non-conductive film exposed outside the chip. However, an additional measurement process may be required to measure the size of the portion of the non-conductive film exposed outside the chip, thereby increasing process time and process cost.

### SUMMARY

Example embodiments provide a semiconductor package having a plurality of structures to measure size of exposed portions of a non-conductive film disposed between stacked semiconductor chips.

Example embodiments provide a method of manufacturing the semiconductor package.

According to example embodiments, a semiconductor package includes a first semiconductor chip having a chip mounting region on a central portion of an upper surface of the first semiconductor chip and a test region surrounding the chip mounting region; a plurality of first measurement structures on the test region and sequentially arranged in a direction perpendicular to an edge of the chip mounting region to be spaced apart from the edge of the chip mounting region; a second semiconductor chip mounted on the chip mounting region of the first semiconductor chip via a plurality of conductive bumps; an adhesive layer filling a gap between the first semiconductor chip and the second semiconductor chip, and the adhesive layer including a central portion on the chip mounting region and at least one overflow portion protruding from the central portion to the test region to contact at least one of the plurality of first measurement structures; and a molding member on the upper surface of the first semiconductor chip to cover side surfaces of the second semiconductor chip.

According to example embodiments, a semiconductor package includes a first semiconductor chip having a chip mounting region on a central portion of an upper surface of the first semiconductor chip and a test region surrounding the chip mounting region; a plurality of first measurement structures on the test region and sequentially arranged to be spaced apart from an edge of the chip mounting region; a plurality of second measurement structures extending from the chip mounting region to the test region; a second semiconductor chip mounted on the chip mounting region of the first semiconductor chip via a plurality of conductive bumps; an adhesive layer filling a gap between the first semiconductor chip and the second semiconductor chip, and the adhesive layer including a central portion on the chip mounting region to contact at least one of the plurality of second measurement structures and at least one overflow portion protruding from the central portion to the test region to contact at least one of the plurality of first measurement structures; and a molding member on the upper surface of the first semiconductor chip to cover side surfaces of the second semiconductor chip.

According to example embodiments, a semiconductor package includes a first semiconductor chip including a first substrate, a plurality of through electrodes penetrating the first substrate, a first wiring layer on a first surface of the first substrate, the first wiring layer having a plurality of first redistribution pads, a plurality of first bonding pads respectively disposed on the plurality of first redistribution pads, and a plurality of second bonding pads respectively disposed on a chip mounting region of a second surface opposite to the first surface of the first substrate; a second semiconductor chip including a second substrate, a second wiring layer on a first surface of the second substrate, the second wiring layer having a plurality of second redistribution pads, and a plurality of third bonding pads respectively disposed on the plurality of second redistribution pads, the second semiconductor chip being mounted on the chip mounting region of the first semiconductor chip via a plurality of conductive bumps respectively disposed between the plurality of second bonding pads and the plurality of third bonding pads; a plurality of first measurement structures on the second surface of the first semiconductor chip parallel to edges of the chip mounting region, the plurality of first measurement structures being sequentially arranged to be spaced apart by a constant distance along a direction from an edge of the chip mounting region toward an edge of the first semiconductor chip that faces the edge of the chip mounting region, a plurality of second measurement structures respectively disposed between ends of each edge of the chip mounting region to extend along a direction perpendicular to each edge of the chip mounting region; an adhesive layer filling a gap between the first semiconductor chip and the second semiconductor chip, the adhesive layer including a central portion on the chip mounting region to contact at least one of the plurality of second measurement structures and at least one overflow portion protruding from the chip mounting region to a test region surrounding the chip mounting region to contact at least one of the plurality of first measurement structures; and a molding member on the second surface of the first semiconductor chip to cover side surfaces of the second semiconductor chip.

According to example embodiments, in a method of manufacturing a semiconductor package, a first semiconductor chip is provided, the first semiconductor chip having a chip mounting region on a center of an upper surface and a test region surrounding the chip mounting region, and the first semiconductor chip having a plurality of first measurement structures disposed on the test region and sequentially arranged to be spaced apart from a side portion of the chip mounting region. A second semiconductor chip is mounted on the chip mounting region of the first semiconductor chip via a plurality of first conductive bumps provided on a lower surface of the second semiconductor chip. An adhesive layer may be formed to fill a gap G between the first semiconductor chip and the second semiconductor chip, the adhesive layer having a central portion provided on the chip mounting region and at least one of overflow portion protruding from the central portion to the test region to contact with at least one of the plurality of first measurement structures. A molding member is formed on the upper surface of the first semiconductor chip to cover side surfaces of the second semiconductor chip. A plurality of second conductive bumps are attached on a lower surface of the first semiconductor chip to be electrically connected to the plurality of the first measurement structures. A distance of the overflow portion is measured by measuring an electrical connection signal through the plurality of second conductive bumps and selecting a portion of the plurality of first measurement structures in which crack is formed.

According to example embodiments, a semiconductor package may include a first semiconductor chip having a chip mounting region on a central portion of an upper surface and a test region surrounding the chip mounting region; a plurality of first measurement structures arranged on the test region and sequentially arranged to be spaced apart from one side portion of the chip mounting region; a second semiconductor chip mounted on the chip mounting region of the first semiconductor chip via a plurality of conductive bumps; an adhesive layer including a central portion and at least one overflow portion protruding from the central portion to the test region to contact to at least one of the plurality of first measurement structures; and a molding member disposed on the upper surface of the first semiconductor chip to cover side surfaces of the second semiconductor chip. Further, a semiconductor package may include a plurality of second measurement structures disposed between both end portions of each of side portions of the chip mounting region to extend from the chip mounting region to the test region, respectively.

According to example embodiments, a method of selective a defective semiconductor package includes contacting a first conductive bump with a measuring device, the first conductive bump being electrically connected to a plurality of first measurement structures positioned on a test region of a first semiconductor chip of the semiconductor package; and measuring, using the measuring device, an electrical value associated with the plurality of first measurement structures; selecting the semiconductor package as defective based on the electrical value, wherein the semiconductor package includes the first semiconductor chip having a chip mounting region on a central portion of an upper surface of the first semiconductor chip and the test region surrounding the chip mounting region; the plurality of first measurement structures on the test region and sequentially arranged in a direction perpendicular to an edge of the chip mounting region to be spaced apart from the edge of the chip mounting region; a second semiconductor chip mounted on the chip mounting region of the first semiconductor chip via a plurality of conductive bumps; an adhesive layer filling a gap between the first semiconductor chip and the second semiconductor chip, and the adhesive layer including a central portion on the chip mounting region and at least one overflow portion protruding from the central portion to the test region to contact at least one of the plurality of first measurement structures; and a molding member on the upper surface of the first semiconductor chip to cover side surfaces of the second semiconductor chip.

The plurality of first measurement structures and the plurality of second measurement structures may each include a triple point at which the adhesive layer, the molding member, and the measurement structure simultaneously contact each other. The plurality of first measurement structures and the plurality of second measurement structures may be electrically connected to a plurality of bonding pads disposed on the lower surface of the first semiconductor chip via a through electrode disposed in the first semiconductor chip.

Accordingly, cracks may occur at the triple point of the plurality of measurement structures due to high stress occurring during a curing process. A portion of the plurality of measurement structures in which the crack is formed may be selected through an EDS (Electrical Die Sorting) process. Thus, a size of the overflow portion of the adhesive layer may be easily measured and products may be sorted according to the measured size of the overflow portion of the adhesive layer.

### BRIEF DESCRIPTION OF THE DRAWINGS

FIG. 1 is a cross-sectional view illustrating a semiconductor package in accordance with example embodiments.

FIG. 2 is a cross-sectional view taken along the line A-A′ in FIG. 1.

FIG. 3 is an enlarged cross-sectional view illustrating the ‘C’ portion of FIG. 2.

FIG. 4 is a cross-sectional view taken along the line B-B′ in FIG. 1.

FIG. 5 is a plan view illustrating measurement structures disposed on a first semiconductor chip from the semiconductor package of FIG. 1.

FIG. 6 is a plan view illustrating a semiconductor package in which a molding member is removed from the semiconductor package of FIG. 1.

FIGS. 7 to 23 are views illustrating a method of manufacturing a semiconductor package in accordance with example embodiments.

FIG. 24 is a flow chart illustrating a method of selective a defective semiconductor package in accordance with example embodiments.

### DETAILED DESCRIPTION OF EXAMPLE EMBODIMENTS

Hereinafter, example embodiments will be explained in detail with reference to the accompanying drawings.

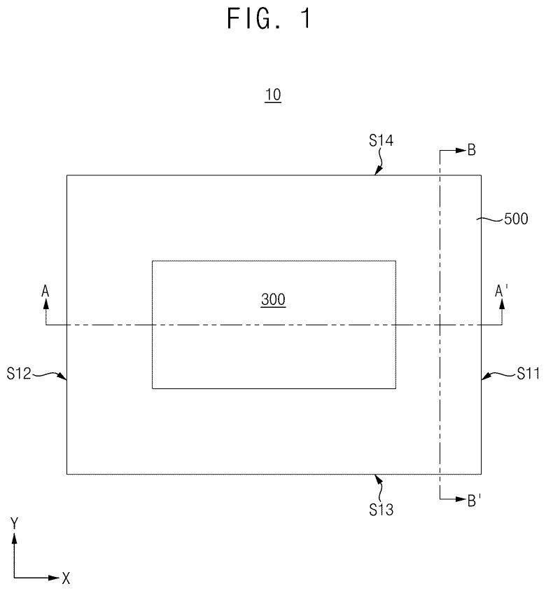

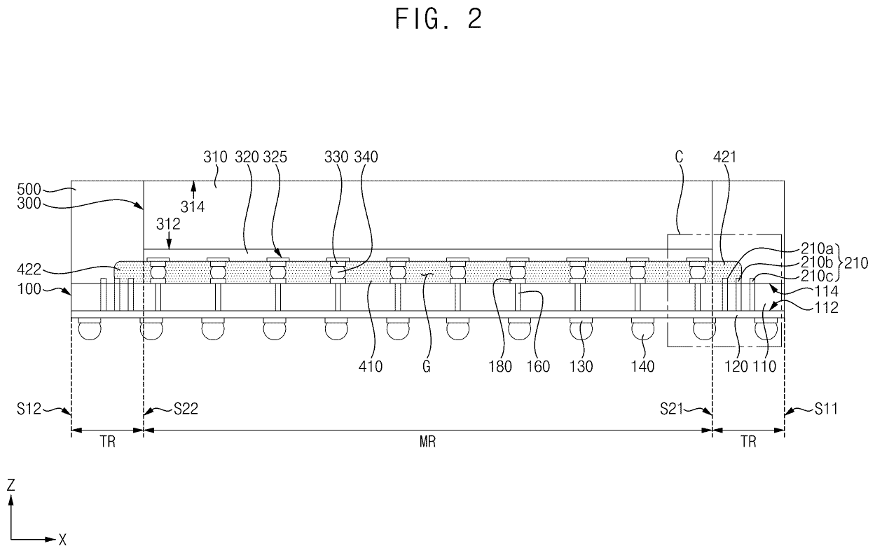

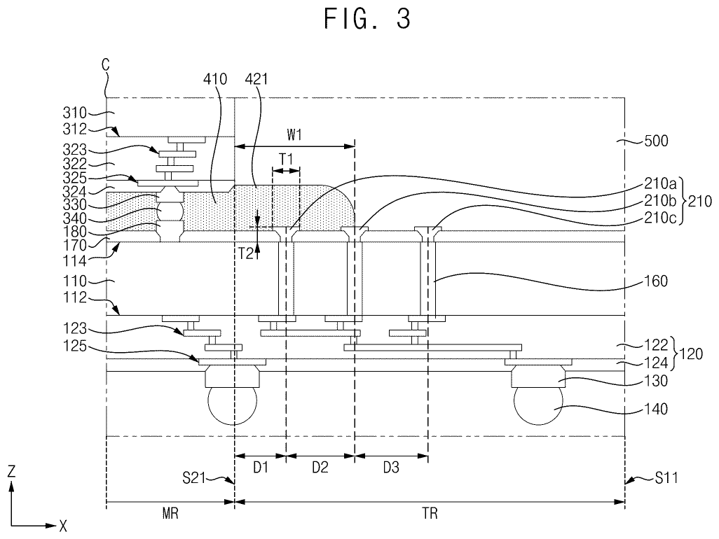

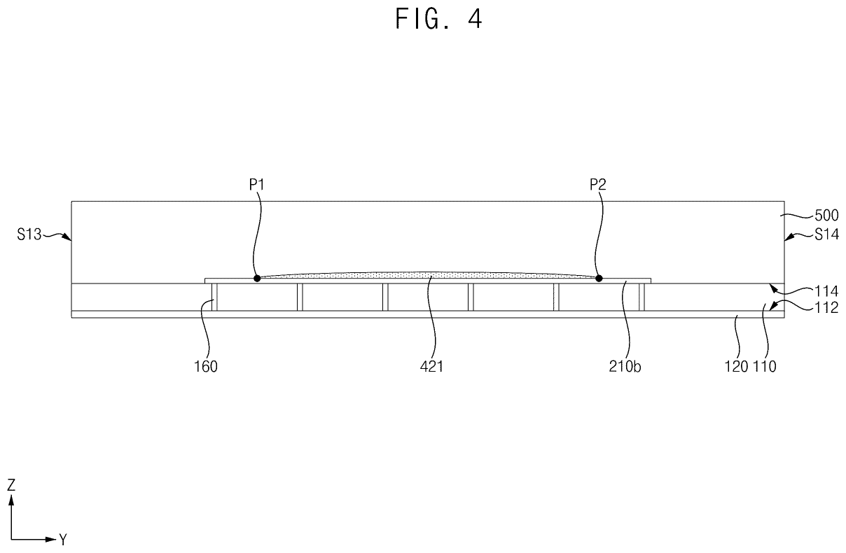

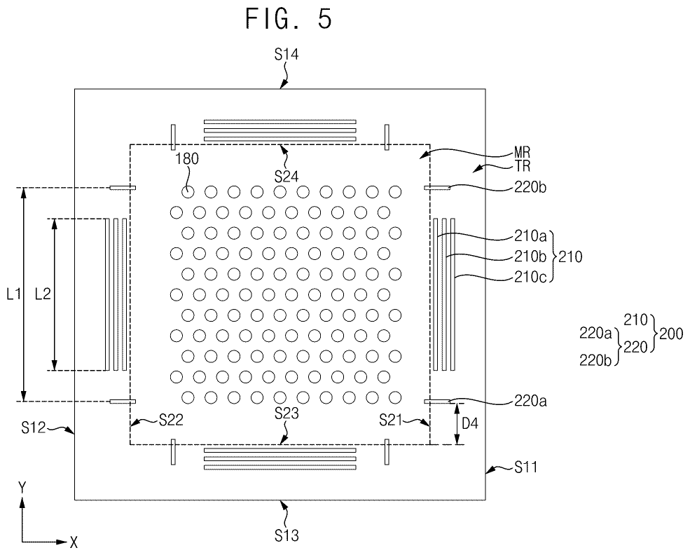

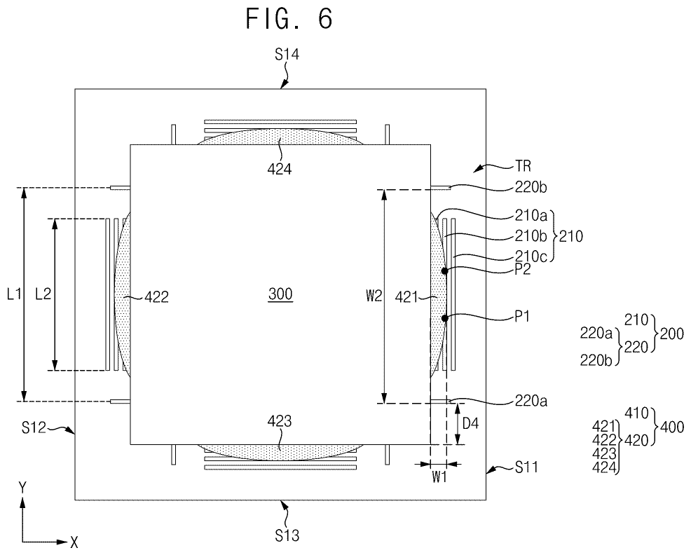

FIG. 1 is a cross-sectional view illustrating a semiconductor package in accordance with example embodiments. FIG. 2 is a cross-sectional view taken along the line A-A′ in FIG. 1. FIG. 3 is an enlarged cross-sectional view illustrating the ‘C’ portion of FIG. 2. FIG. 4 is a cross-sectional view taken along the line B-B′ in FIG. 1. FIG. 5 is a plan view illustrating measurement structures disposed on a first semiconductor chip from the semiconductor package of FIG. 1. FIG. 6 is a plan view illustrating a semiconductor package in which a molding member is removed from the semiconductor package of FIG. 1.

Referring to FIGS. 1 to 6, a semiconductor package 10 may include a first semiconductor chip 100, a second semiconductor chip 300 stacked on the first semiconductor chip 100, an adhesive layer 400 disposed between the first semiconductor chip 100 and the second semiconductor chip 300, and a plurality of measurement structures 200 disposed on the first semiconductor chip 100. Additionally, the semiconductor package 10 may further include a molding member 500.

Additionally, the semiconductor package 10 may be a multi-chip package (MCP) including different types of semiconductor chips. The semiconductor package 10 may be a system in package (SIP) that has an independent function by stacking or arranging a plurality of semiconductor chips in one package.

For example, the semiconductor package 10 may include a first semiconductor chip 100 as a logic chip and a second semiconductor chip 300 as a memory chip that are sequentially stacked. The first semiconductor chip 100 may be a logic chip including a logic circuit. The logic chip may be a controller that controls memory elements of the second semiconductor chip 300. The first semiconductor chip may be a processor chip such as an ASIC as a host such as a CPU, GPU, or SOC, or an application processor (AP). The second semiconductor chip may include DRAM, SRAM, etc. Alternatively, the first semiconductor chip 100 and the second semiconductor chip 300 may be selected as either a logic chip or a memory chip.

The various pads of a device described herein may be conductive terminals connected to internal wiring of the device, and may transmit signals and/or supply voltages between an internal wiring and/or internal circuit of the device and an external source. For example, chip pads of a semiconductor chip may electrically connect to and transmit supply voltages and/or signals between an integrated circuit of the semiconductor chip and a device to which the semiconductor chip is connected. The various pads may be provided on or near an external surface of the device and may generally have a planar surface area (often larger than a corresponding surface area of the internal wiring to which they are connected) to promote connection to a further terminal, such as a bump or solder ball, and/or an external wiring.

In example embodiments, the first semiconductor chip 100 may include a first substrate 110, a first wiring layer 120, a plurality of first bonding pads 130, a plurality of through electrodes 160 and a plurality of second bonding pads 180. Additionally, the first semiconductor chip 100 may further include a plurality of first conductive bumps 140 as first conductive connection members provided on each of the plurality of first bonding pads 130. For example, the plurality of first conductive bumps 140 may include solder bumps. When viewed from a plan view, the first semiconductor chip 100 may have a rectangular shape including first to fourth edges S11, S12, S13, and S14.

The first substrate 110 may have a first surface 112 and a second surface 114 opposite to each other. The first surface 112 may be an active surface, and the second surface 114 may be an inactive surface. A plurality of circuit patterns and cells may be formed on the first surface 112 of the first substrate 110. For example, the first substrate 110 may be a single crystal silicon substrate. The plurality of circuit patterns may include transistors, capacitors, diodes, etc. The plurality of circuit patterns may constitute the plurality of circuit elements. Accordingly, the first semiconductor chip 100 may be a semiconductor device with the plurality of circuit elements formed therein.

The first wiring layer 120 may be provided on the first surface 112 of the first substrate 110, that is, the active surface. The first wiring layer 120 may include a plurality of insulation layers and upper wirings within the insulation layers. Additionally, a plurality of redistribution pads 125 may be provided on an outermost insulation layer of the first wiring layer 120, and the plurality of first bonding pads 130 may be provided on the plurality of redistribution pads 125, respectively (see, e.g., FIG. 3).

It will be understood that when an element is referred to as “contacting” or “in contact with” another element (or using any form of the word “contact”), there are no intervening elements present at the point of contact.

The plurality of through electrodes (e.g., through silicon via, TSV) 160 may be provided to vertically penetrate the first substrate 110 from the first surface 112 of the first substrate 110 to the second surface 114 of the first substrate 110. A plurality of first ends of the plurality of through electrodes 160 may be in contact with the upper wiring of the first wiring layer 120. However, the present invention is not limited thereto, and for example, the plurality of through electrodes 160 may be provided to penetrate the first wiring layer 120 and contact the plurality of first bonding pads 130.

The first backside insulation layer 170 may be provided on the second surface 114 of the first substrate 110, that is, the inactive surface. The plurality of second bonding pads 180 may be provided on the first backside insulation layer 170. The plurality of second bonding pads 180 may be disposed on exposed surfaces of the plurality of through electrodes 160. Accordingly, the plurality of first and second bonding pads 130 and 180 may be electrically connected to each other by the plurality of the through electrodes 160.

The second surface 114 of the first substrate 110 may include a chip mounting region MR and a test region TR. The chip mounting region MR may be a rectangular area provided at a central portion of the second surface 114. The chip mounting region MR may include first to fourth edges S21, S22, S23, and S24. The second bonding pads 180 may be arranged on the chip mounting region MR in an array form (see, e.g., FIG. 5). The test region TR may be an area provided on an outer portion of the second surface 114 to surround the chip mounting region MR. For example, the test region TR may be an area of the second surface 114 excluding the chip mounting region MR.

The plurality of first and second bonding pads 130 and 180 may be arranged in respective arrays on the upper and lower surfaces 112 and 114 of the first semiconductor chip 100, and the plurality of through electrodes 160 may be disposed in an array in the first substrate 110. For example, a via arrangement of the plurality of through electrodes 160 may correspond to a pad arrangement of the plurality of second bonding pads 180.

A line-shaped layout feature in a given layer is characterized as having a consistent vertical cross-section shape and extending in a single direction over the substrate. Thus, the line-shaped layout features define structures that are one-dimensionally varying. An item described with a phrase such as “a metal line” has only a linear shape in the designated direction.

In example embodiments, a plurality of measurement structures 200 may include a plurality of first measurement structures 210 and a plurality of second measurement structures 220. The plurality of first measurement structures 210 and the plurality of second measurement structures 220 may include a plurality of metal lines or wires having a predetermined width T1 and a predetermined height T2 (see, e.g., FIG. 3). For example, the predetermined width T1 and the predetermined height T2 of the plurality of first measurement structures 210 and the plurality of second measurement structures 220 may be within a range of 1 μm to 3 μm. For example, the plurality of metal lines may include metal material such as copper (Cu).

The plurality of first measurement structures 210 and the plurality of second measurement structures 220 may be electrically connected to a first redistribution wiring 123 of the first semiconductor chip 100 by the plurality of through electrodes 160 of the first semiconductor chip 100. The first redistribution wiring 123 may be electrically connected to the plurality of first bonding pads 130 that are provided on the lower surface 112 of the first substrate 110 of the first semiconductor chip 100.

It will be understood that when an element is referred to as being “connected”, “coupled” to, “on”, “provided on”, or “disposed on” another element, it can be directly connected or coupled to or on the other element or intervening elements may be present.

The plurality of first measurement structures 210 and the plurality of second measurement structures 220 may be disposed on the upper surface 114 of the first substrate 110 of the first semiconductor chip 100. For example, the plurality of first measurement structures 210 and the plurality of second measurement structures 220 may be disposed on the test region TR adjacent to the edges of the chip mounting region MR of the first semiconductor chip 100.

The plurality of first measurement structures 210 may include a first width measurement structure 210a, a second width measurement structure 210b and a third width measurement structure 210c.

The plurality of first measurement structures 210 may be disposed on the test region TR of the first semiconductor chip 100. For example, the plurality of first measurement structures 210 may be sequentially arranged from the first edge S21 of the chip mounting region MR toward the first edge S11 of the first semiconductor chip 100 (see, e.g., FIG. 5). For example, the first width measurement structure 210a may be disposed on the test region TR to be spaced apart from the first edge S21 of the chip mounting region MR along the first direction (X direction) by a first distance D1 (see, e.g., FIG. 3). The second width measurement structure 210b may be disposed on the test region TR to be spaced apart from the first width measurement structure 210a in the first direction (X direction) by a second distance D2. The third width measurement structure 210c may be disposed on the test region TR to be spaced apart from the second width measurement structure 210b in the first direction (X direction) by a third distance D3.

The plurality of first measurement structures 210 may be arranged on the test region TR of the first semiconductor chip 100 such that the plurality of first measurement structures 210 are sequentially away from one of the edges of the chip mounting region MR at equal intervals. For example, the first to third width measurement structure 210a, 210b and 210c may be sequentially arranged from the first edge S21 of the chip mounting region MR at equal intervals. The first distance D1, the second distance D2, and the third distance D3 may be the same. For example, the first distance D1, the second distance D2, and the third distance D3 may be within a range of 15 μm to 100 μm.

The plurality of first measurement structures 210 may be arranged to extend in a direction parallel to an extension direction of the edge of the chip mounting region MR to which they are adjacent. Additionally, the plurality of first measurement structures 210 may be arranged to extend in a direction perpendicular to the extension direction of the edge of the chip mounting region MR. For example, the first width measurement structure 210a, the second width measurement structure 210b, and the third width measurement structure 210c disposed on an area adjacent to the first edge S21 of the chip mounting region MR may extend parallel to the second direction (Y direction). Additionally, the first width measurement structure 210a, the second width measurement structure 210b, and the third width measurement structure 210c disposed on an area adjacent to the third edge S23 of the chip mounting region MR may extend in the first direction (X direction). The number and lengths of the plurality of first measurement structures 210 may be determined in consideration of the overall size of the package and the sizes of semiconductor chips included in the package. The plurality of first measurement structures 210 may be arranged adjacent to and along edges of a second semiconductor chip 300, when viewed in plan view, when the second semiconductor chip 300 is mounted on the first semiconductor chip 100 as described below.

Although only a few first measurement structures 210 are shown in the drawings, it should be understood that the number and shape of the plurality of first measurement structures 210 are illustrative, and that the present invention is not limited thereto.

The plurality of second measurement structures 220 may include a first coverage measurement structure 220a and a second coverage measurement structure 220b. The plurality of second measurement structures 220 may extend from the chip mounting region MR of the first semiconductor chip 100 to the test region TR of the first semiconductor chip 100. For example, each second measurement structure 220 may extend across the boundary between the chip mounting region MR and the test region TR in a direction intersecting the direction of the boundary at the point of crossing.

The plurality of second measurement structures 220 may extend from the chip mounting region MR to the test region TR to cross a boundary portion between the chip mounting region MR and the test region TR. For example, the first coverage measurement structure 220a and the second coverage measurement structure 220b may be disposed between both ends of the first edge S21 of the chip mounting region MR to cross the first edge S21 of the chip mounting region MR. For example, the first coverage measurement structure 220a may be disposed adjacent to the third edge S23 of the chip mounting region MR, and the second coverage measurement structure 220b may be disposed adjacent to the fourth edge S24 of the chip mounting region MR.

The plurality of second measurement structures 220 may be disposed adjacent to corner areas of the chip mounting region to cross the edges of the chip mounting region MR. For example, the first coverage measurement structure 220a may be disposed adjacent to a first corner where the first edge S21 and the third edge S23 meet each other to cross the first edge S21. The second coverage measurement structure 220b may be disposed adjacent to a second corner where the first edge S21 and the fourth edge S24 meet each other to cross the first edge S21. For example, a distance from a second measurement structure 220 to its corresponding corner may be less than a distance from a corresponding first measurement structure 210 to the corner. The corresponding first measurement structure 210 may be adjacent to the edge of the mounting region MR that is crossed by the second measurement structure 220.

The plurality of second measurement structures 220 may be spaced apart from a corner of the chip mounting region MR toward a center of the edge of chip mounting region MR by a predetermined distance. For example, the first coverage measurement structure 220a may be disposed to be spaced apart from the corner of the chip mounting region MR by a fourth distance D4 toward the center of the first edge S21 of the chip mounting region MR (see, e.g., FIG. 5). The fourth distance D4 may be within a range of 500 μm to 1500 μm.

The plurality of second measurement structures 220 may extend in a direction perpendicular to the edge of the chip mounting region MR of the first semiconductor chip 100. For example, the first coverage measurement structure 220a and the second coverage measurement structure 220b may extend in a direction perpendicular to the first edge S21 to cross the first edge S21 of the chip mounting region MR.

The plurality of second measurement structures 220 may be disposed to be closer to the chip mounting region MR of the first semiconductor chip 100 than the plurality of first measurement structures 210.

A distance between second measurement structures 220 that cross the same edge of the chip mounting region MR may be greater than a length of each of the plurality of first measurement structures 210. For example, the distance between the first coverage measurement structure 220a and the second coverage measurement structure 220b may be a first length L1 along the first edge S21 of the chip mounting region MR in the second direction (Y direction). The length of each of the first measurement structures 210 may be a second length L2. The first length L1 may be greater than the second length L2. For example, the first length L1 may be smaller than the length of the first edge S21 of the chip mounting region MR of the first semiconductor chip 100.

In example embodiments, the second semiconductor chip 300 may include a second substrate 310, a second wiring layer 320 and a plurality of third bonding pads 330. Additionally, the second semiconductor chip 300 may further include a plurality of second conductive bumps 340 as second conductive connection members disposed on the plurality of third bonding pads 330, respectively. The second semiconductor chip 300 may be mounted on the chip mounting region MR of the first semiconductor chip 100 via the plurality of second conductive bumps 340 and have a gap G provided between the first semiconductor chip 100 and the second semiconductor chip 300. For example, the plurality of second conductive bumps 340 may include solder bumps. The edges of the second semiconductor chip 300 in plan view may be coextensive with the edges of the chip mounting region MR of the first semiconductor chip 100.

The second substrate 310 may have a first surface 312 and a second surface 314 opposed to each other. The first surface 312 may be an active surface, and the second surface 314 may be an inactive surface. A plurality of circuit elements may be formed on the first surface 312 of the second substrate 310. The plurality of circuit elements may include a plurality of memory elements. The memory elements may be volatile semiconductor memory devices and non-volatile semiconductor memory devices. An insulation interlayer may be formed on the first surface 312 of the second substrate 310 to cover the plurality of circuit elements.

The second wiring layer 320 may include a metal wiring layer 322 and a protective layer 324 sequentially stacked on the first surface 312 of the second substrate 310. The metal wiring layer 322 may include a plurality of insulation layers, a plurality of upper wirings 323 within the plurality of insulation layers and a plurality of redistribution pads 325 as uppermost wirings. The protective layer 324 may be formed on the metal wiring layer 322 to cover the plurality of redistribution pads 325.

The plurality of redistribution pads 325 may be electrically connected to the plurality of circuit elements through upper wirings 323 and contact plugs in the insulation interlayer. The plurality of third bonding pads 330 may be disposed on at least a portion of the plurality of redistribution pads 325. The plurality of third bonding pads 330 may be electrically connected to the plurality of redistribution pad 325, respectively.

The size and thickness of the first and second semiconductor chips and the number, size, and arrangement of the insulation layer of the wiring layer, the upper wirings and the redistribution pads are provided as examples, and it will be understood that the present invention is not limited thereto.

The plurality of second conductive bumps 340 may be provided on the plurality of third bonding pads 330, respectively. For example, the plurality of second conductive bumps 340 of the second semiconductor chip 300 may be bonded to the plurality of second bonding pads 180 of the first semiconductor chip by a flip chip bonding process, respectively. Accordingly, the plurality of third bonding pads 330 of the second semiconductor chip 300 may be electrically connected to the plurality of second bonding pads 180 of the first semiconductor chip 100 by the plurality of second conductive bumps 340, respectively.

In example embodiments, the adhesive layer 400 may fill the gap G between the first semiconductor chip 100 and the second semiconductor chip 300 to cover the plurality of second conductive bumps 340. For example, the adhesive layer 400 may include a non-conductive film (NCF).

For example, the second semiconductor chip 300 and the first semiconductor chip 100 may be attached to each other through a thermal compression bonding process using the non-conductive film. In the thermal compression bonding process, the non-conductive film may change into a liquid and have a fluidity. The liquefied non-conductive film may flow between the plurality of second conductive bumps 340 disposed between the second semiconductor chip 300 and a first wafer including the first semiconductor chip 100, and then the liquefied non-conductive film may be hardened to cover the second conductive bumps 340 and fill the gap G disposed under the second semiconductor chip 300.

The cured adhesive layer 400 may have a central portion 410 that fills the gap G under the second semiconductor chip 300 and a plurality of fillet portions (e.g., bulges or overflow portions) 420 protruding from edges of the second semiconductor chip 300 to the test region TR of the first semiconductor chip 100. The plurality of overflow portions 420 may include a first overflow portion 421, a second overflow portion 422, a third overflow portion 423 and a fourth overflow portion 424. For example, the first overflow portion 421 may protrude from the first edge S21 of the chip mounting region MR toward the first edge S11 of the first semiconductor chip 100. The second overflow portion 422 may protrude from the second edge S22 of the chip mounting region MR toward the second edge S12 of the first semiconductor chip 100. The third overflow portion 423 may protrude from the third edge S23 of the chip mounting region MR toward the third edge S13 of the first semiconductor chip 100. The fourth overflow portion 424 may protrude from the fourth edge S24 of the chip mounting region MR toward the fourth edge S14 of the first semiconductor chip 100.

Each of the plurality of overflow portions 420 of the cured adhesive layer 400 may be in contact with at least one of the plurality of first measurement structures 210. A distance from the edge of the second semiconductor chip 300 to the farthest one of the plurality of first measurement structures 210 that are in contact with the overflow portion may be a first width W1 of the overflow portions 420. For example, as shown, e.g., in FIG. 6, the first overflow portion 421 may contact the first width measurement structure 210a and the second width measurement structure 210b among the plurality of first measurement structures 210. Thus, the first width W1 of the first overflow portion 421 may be a distance from the edge of the second semiconductor chip 300 to the second width measurement structure 210b. For example, the first width W1 of the first overflow portion 421 may be the same as or similar to a sum of the first distance D1, which is a distance from the first edge S21 of the chip mounting region MR to the first width measurement structure 210a, and the second distance D2, which is the distance from the first width measurement structure 210a to the second width measurement structure 210b.

The central portion 410 of the cured adhesive layer 400 may contact at least one of the plurality of second measurement structures 220. For example, the central portion 410 of the cured adhesive layer 400 may contact the first coverage measurement structure 220a and the second coverage measurement structure 220b disposed between both end portions of the first edge S21 of the chip mounting region MR. A width of the central portion 410 adjacent to the first edge S21 may be a second width W2. The second width W2 may be equal to or similar to the first length L1 between the first coverage measurement structure 220a and the second coverage measurement structure 220b.

In example embodiments, the molding member 500 may be disposed on the on the first semiconductor chip 100 to cover the second semiconductor chip 300 and a portion of the cured adhesive layer 400. The molding member 500 may cover side surfaces of the second semiconductor chip 300. An upper surface, that is, a backside surface, of the second semiconductor chip 300 may be exposed from the molding member 500. For example, the molding member 500 may include a thermosetting resin.

The molding member 500 may include a plurality of points where the measurement structures 200 and the adhesive layer 400 are in contact simultaneously. For example, the molding member 500 may include a first point P1 and a second point P2 (see, e.g., FIG. 4) that are points at which the second width measurement structure 210b and the first overflow portion 421 are in contact simultaneously. For example, the points P1 and P2 may be triple points at which the boundaries of the measurement structure 200, the adhesive layer 400, and the molding member 500 come together.

As mentioned above, the semiconductor package 10 may include a first semiconductor chip 100, a second semiconductor chip 300 stacked on the first semiconductor chip 100, an adhesive layer 400 to fill the gap G between the first semiconductor chip 100 and the second semiconductor chip 300 and have the central portion 410 and the plurality of overflow portions 420 and the plurality of measurement structures 200 disposed on the first semiconductor chip 100. Additionally, the semiconductor package 10 may further include a molding member 500.

The plurality of first measurement structures 210 and the plurality of second measurement structures 220 may include a triple point that simultaneously contact with the adhesive layer 400 and the molding member 500. The plurality of first measurement structures 210 and the plurality of second measurement structures 220 may be electrically connected to the plurality of first bonding pads 130 disposed on the lower surface of the first semiconductor chip 100 via the through electrode 160 disposed in the first semiconductor chip 100.

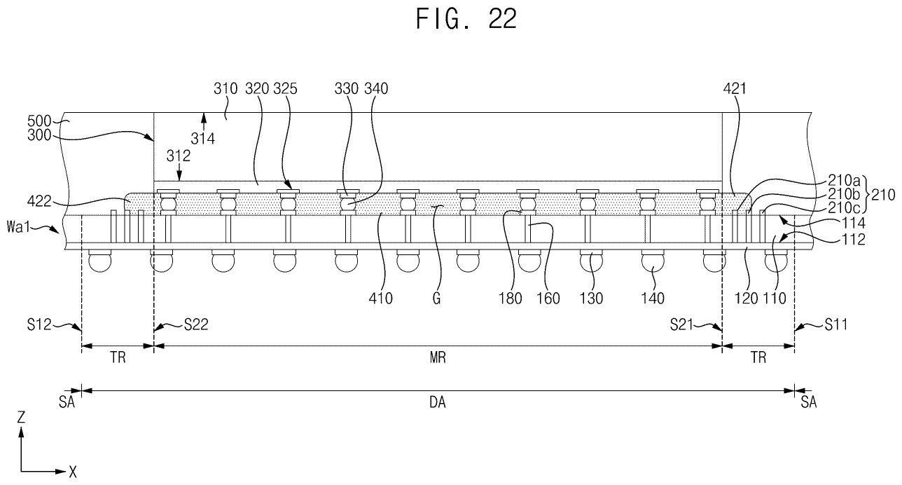

Accordingly, cracks may occur at the triple point of the plurality of measurement structures 200 due to high stress occurring during a curing process. And, a portion of the plurality of measurement structures 200 that crack is formed may be selected through an EDS (Electrical Die Sorting) process. Thus, a size of the overflow portion 420 of the adhesive layer 400 may be easily measured as described below with reference to FIGS. 22-24.

Hereinafter, a method of manufacturing the semiconductor package of FIG. 1 will be described.

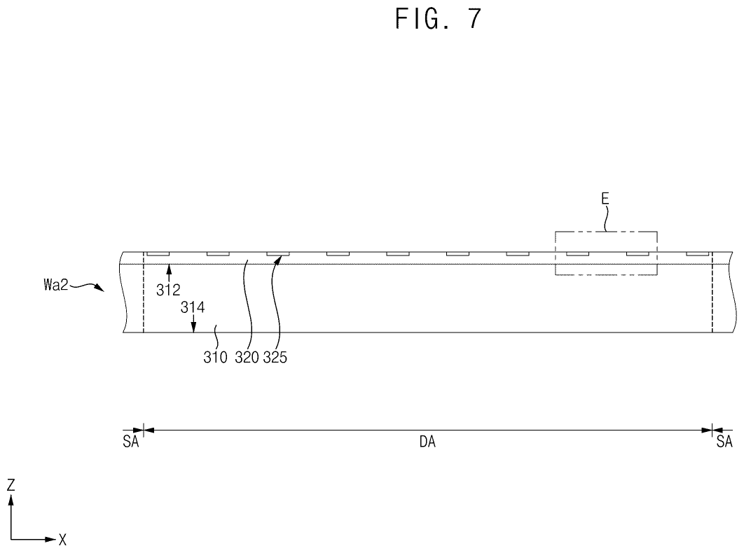

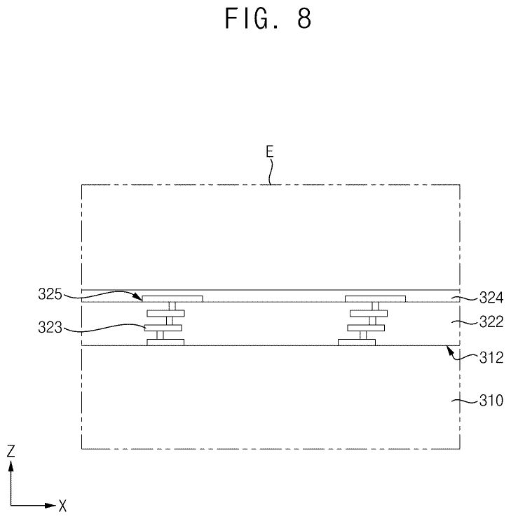

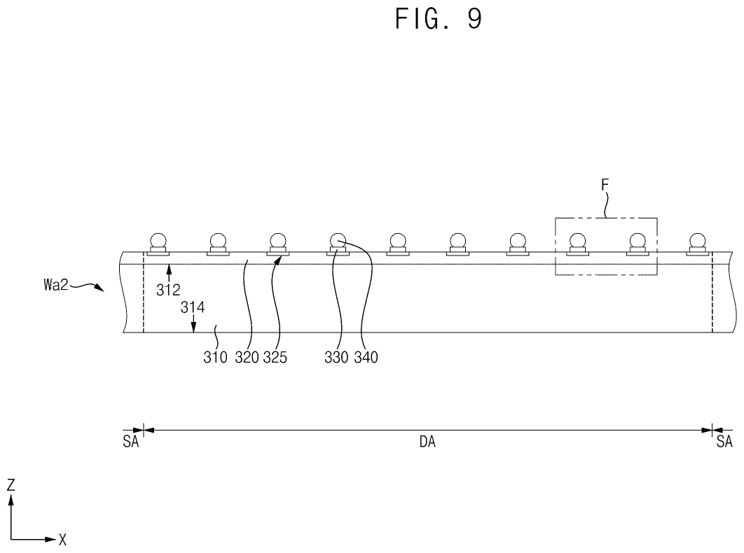

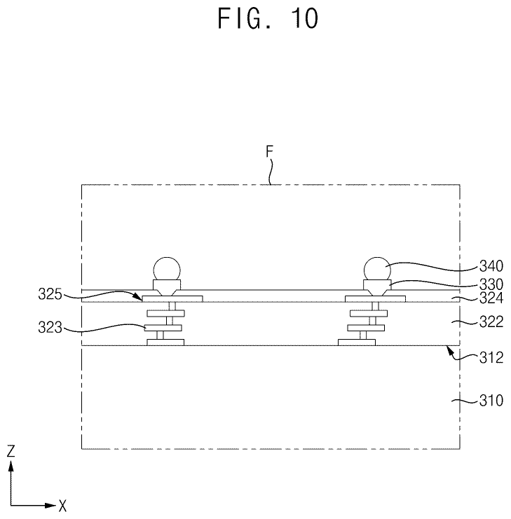

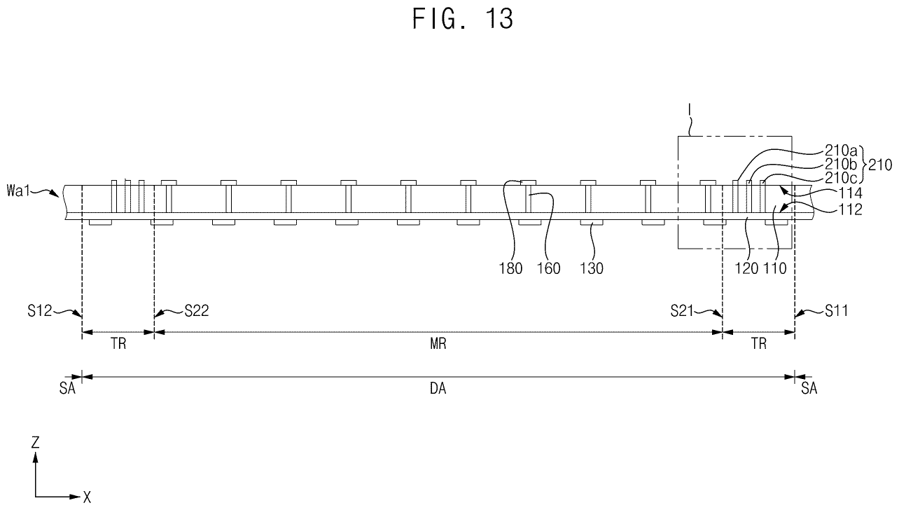

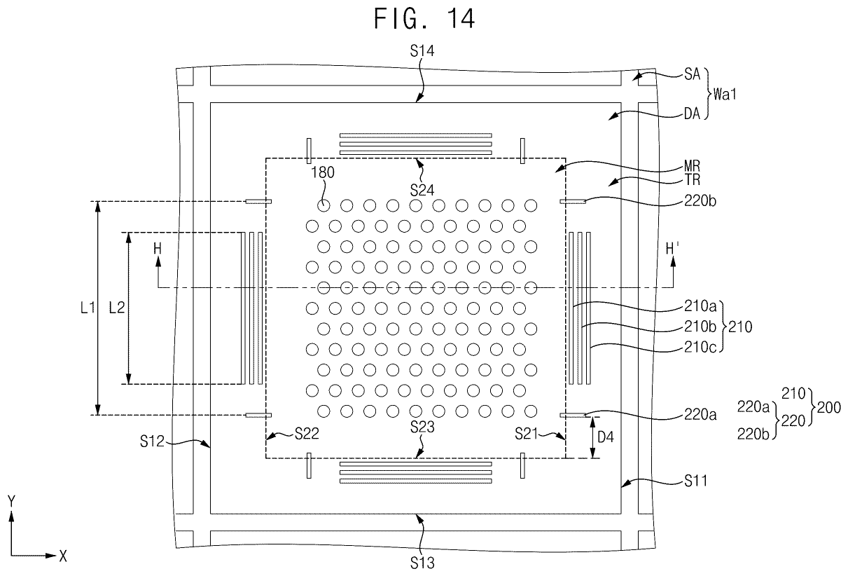

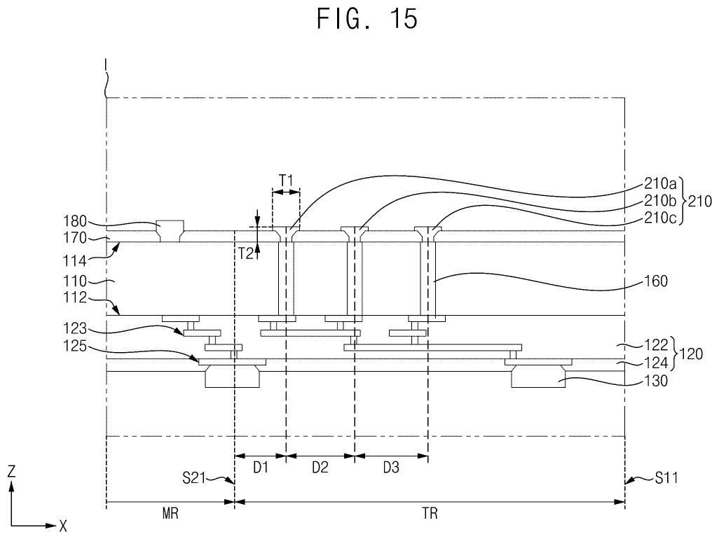

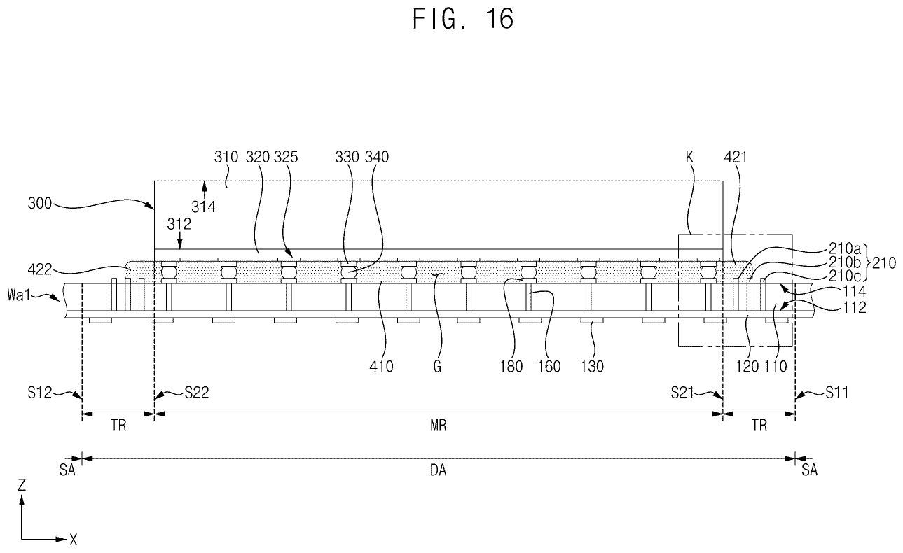

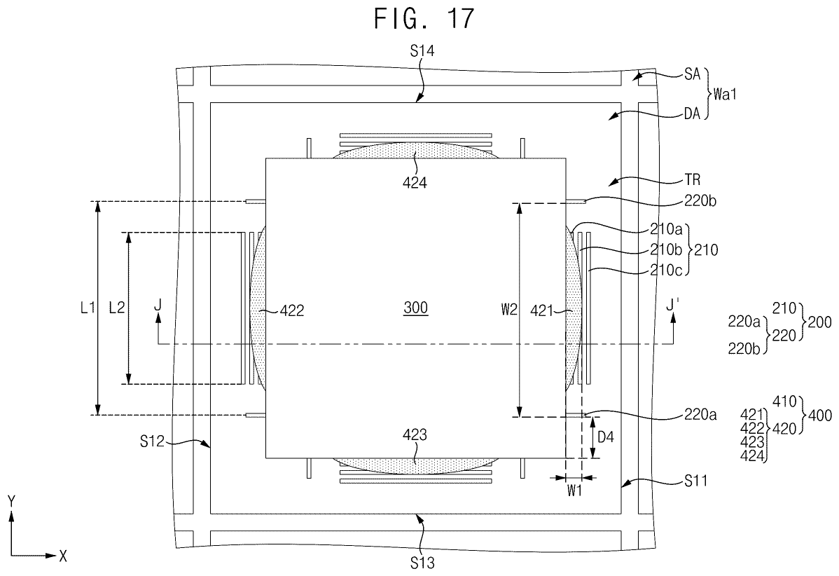

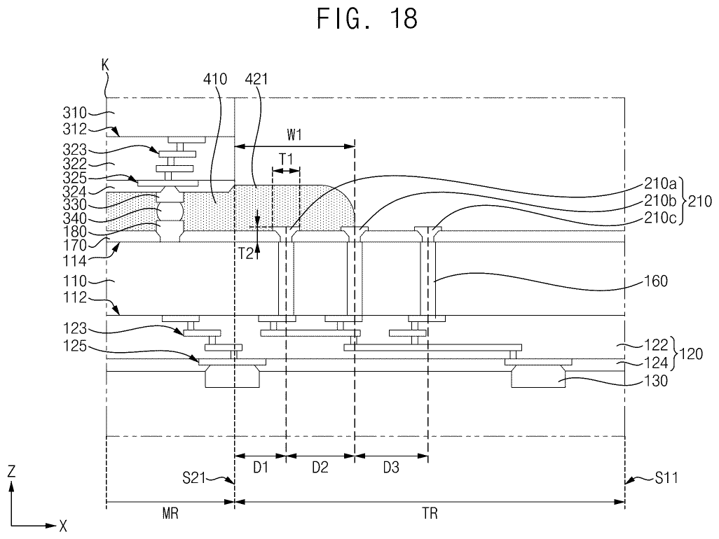

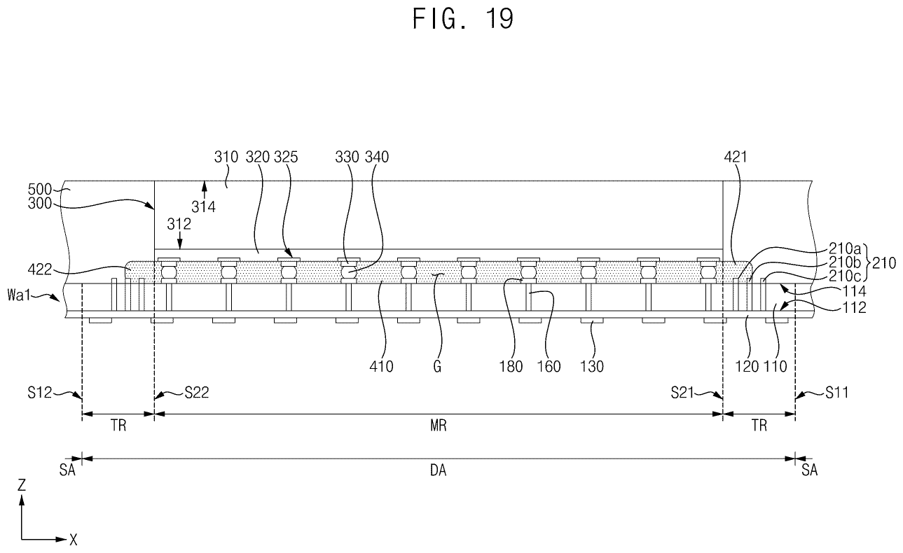

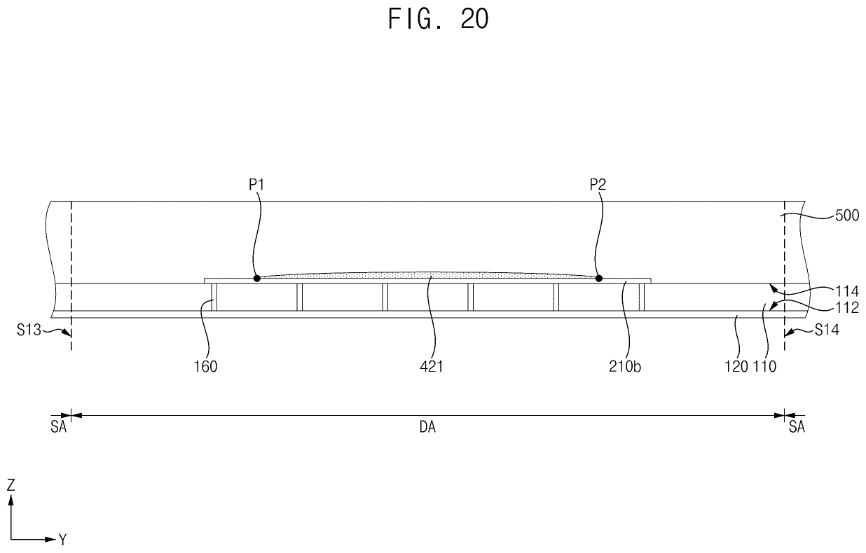

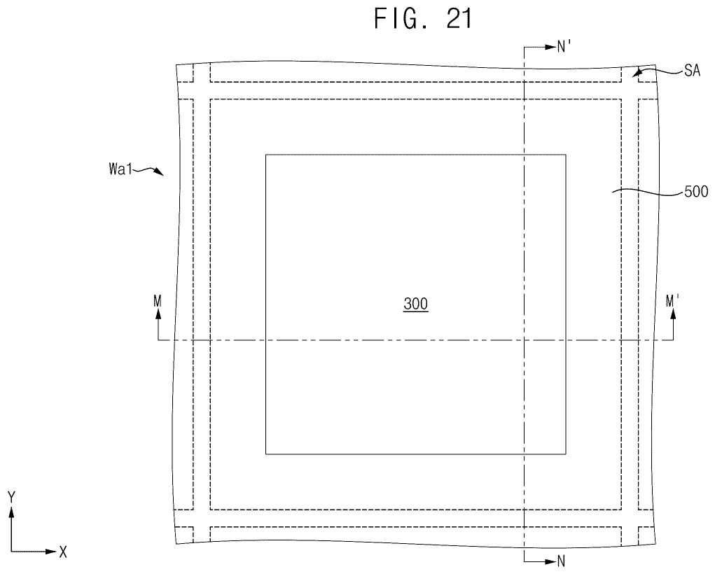

FIGS. 7 to 23 are views illustrating a method of manufacturing a semiconductor package in accordance with example embodiments. FIG. 8 is an enlarged cross-sectional view illustrating the portion ‘E’ of FIG. 7. FIG. 10 is an enlarged cross-sectional view illustrating the portion ‘F’ of FIG. 9. FIG. 13 is a cross-sectional view taken along the line H-H′ in FIG. 14. FIG. 15 is an enlarged cross-sectional view illustrating the portion ‘I’ of FIG. 13. FIG. 16 is a cross-sectional view taken along the line J-J′ in FIG. 17. FIG. 18 is an enlarged cross-sectional view illustrating the portion ‘K’ of FIG. 16. FIG. 19 is a cross-sectional view taken along the line M-M′ in FIG. 21. FIG. 20 is a cross-sectional view taken along the line N-N′ in FIG. 21.

Referring to FIGS. 7 and 8, a second wafer Wa2 on which a plurality of second semiconductor chips (dies) is formed may be provided.

In example embodiments, the second wafer Wa2 may include a second substrate 310 having a first surface 312 and a second surface 314 opposite to the first surface 312. The second substrate 310 may include a die region DA and a scribe lane region SA surrounding the die region DA. As will be described below, the second substrate 310 may be cut along the scribe lane region SA that divides the plurality of die regions DA of the second wafer Wa2 through a sawing process to be individualized into a plurality of second semiconductor chips.

A plurality of circuit elements may be formed on the die region DA of the first surface 312 of the second substrate 310. The circuit element may include a plurality of memory elements. For example, the memory devices may include volatile semiconductor memory devices and non-volatile semiconductor memory devices. For example, the volatile semiconductor memory device may include DRAM, SRAM, etc. For example, the non-volatile semiconductor memory devices may include EPROM, EEPROM, and Flash EEPROM. Alternatively, the second semiconductor chip may be a logic chip including a logic circuit. The logic chip may be a controller that controls memory devices. For example, the second semiconductor chip may be a processor chip such as an ASIC as a host such as a CPU, GPU, or SOC, or an application processor.

For example, the second substrate 310 may be formed of or include a semiconductor material such as silicon, germanium, silicon-germanium, etc., or a group III-V compound semiconductor such as gallium phosphide (GaP), gallium arsenide (GaAs), or gallium antimonide (GaSb), etc. According to some embodiments, the second substrate 310 may be a Silicon-On-Insulator (SOI) substrate or a Germanium-On-Insulator (GOI) substrate.

The circuit elements may include, for example, a transistor, a capacitor, a wiring structure, etc. The circuit elements may be formed on the first surface 312 of the second substrate 310 by performing a fab process called front-end-of-line (FEOL) for manufacturing semiconductor devices. The surface of the second substrate on which the FEOL process is performed may be referred to as the front surface of the second substrate, and a surface opposite to the front surface may be referred to as the backside surface. An insulation interlayer may be formed on the first surface 312 of the second substrate 310 to cover the plurality of circuit elements.

In example embodiments, the second wafer Wa2 may include a second wiring layer 320 provided on the second substrate 310. The second wiring layer 320 may include a metal wiring layer 322 and a protective layer 324 sequentially stacked on the second substrate 310. The second wiring layer may be formed by performing a wiring process called back-end-of-line (BEOL).

The metal wiring layer 322 may include a plurality of insulation layers, upper wirings 323 within the plurality of insulation layers, and redistribution pads 325 as uppermost wirings. The protective layer 324 may be formed on the metal wiring layer 322 to cover the redistribution pads 325.

For example, the insulation layers may be formed of or include oxides such as silicon oxide, carbon-doped oxide, fluorine-doped oxide, etc. The protective layer may be formed of or include a passivation layer including a nitride such as silicon nitride (SiN). Additionally, the protective layer may be sequentially stacked and include a first passivation layer including an oxide layer and a second passivation layer including a nitride layer. The upper wiring and the redistribution pads may be formed of or include a metal material such as aluminum (Al), copper (Cu), etc.

The redistribution pads 325 may be electrically connected to the plurality of circuit elements through the upper wirings 323 and contact plugs in the insulation interlayer. As will be described below, a bonding pad may be formed on at least a portion of the redistribution pad 325 to be electrically connected to an external device.

It will be understood that the number, size, and arrangement of the insulation layers, upper wirings, and redistribution pads of the wiring layer are provided as examples, and the present invention is not limited thereto.

Referring to FIGS. 9 and 10, a plurality of third bonding pads 330 may be formed on the plurality of redistribution pads 325 respectively, and a plurality of second conductive bumps 340 may be formed on the plurality of third bonding pads 330 respectively.

In example embodiments, portions of the protective layer 324 may be removed to expose at least portions of the plurality of redistribution pads 325.

For example, a photoresist film may be formed on the protective layer 324, and an exposure process may be performed to form a photoresist pattern having openings that expose the portions of the protective layer 324, and the protective layer 324 may be partially removed by using the photoresist pattern as an etch mask.

Subsequently, the plurality of third bonding pads 330 may be formed on the exposed portions of the plurality of redistribution pads 325 respectively. For example, the plurality of third bonding pads 330 may be formed by a plating process.

Subsequently, the plurality of second conductive bumps 340 may be formed on the plurality of third bonding pads 330, respectively. For example, a plating process may be performed to form the plurality of second conductive bumps 340. Specifically, a seed layer may be formed on the plurality of third bonding pads 330 on the protective layer 324, a photoresist pattern may be formed to have the openings that expose partial areas of the seed layer, and the openings may be filled up with a conductive material, the photoresist pattern may be removed and a reflow process may be performed to form the plurality of second conductive bumps 340. Alternatively, the plurality of second conductive bumps may be formed by a screen-printing method, a deposition method, or the like. The plurality of second conductive bumps may include solder bumps.

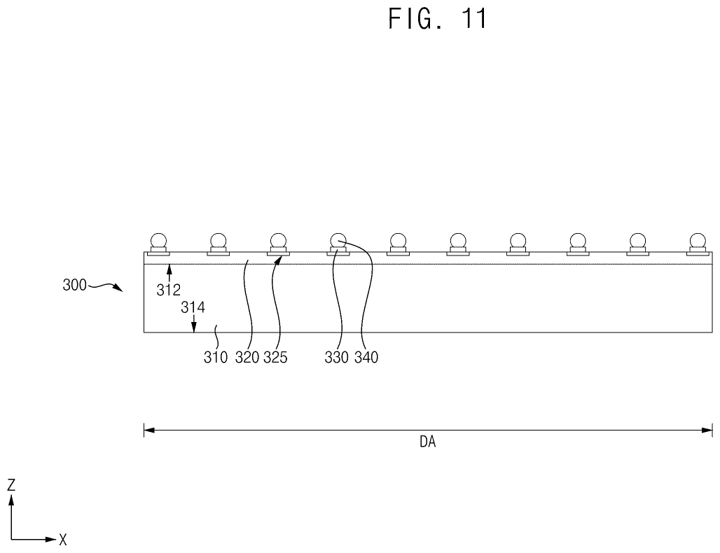

Referring to FIG. 11, the second wafer Wa2 may be cut along the scribe lane region SA to form an individualized second semiconductor chip 300. The second wafer Wa2 may be cut by a sawing process.

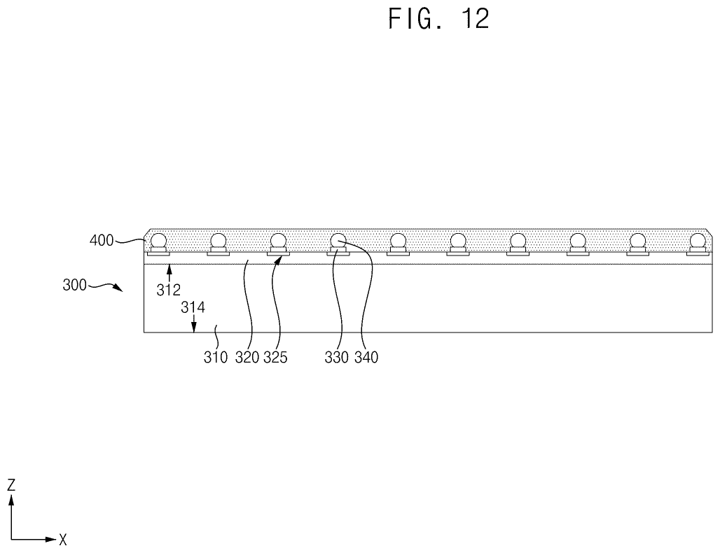

Referring to FIG. 12, an adhesive layer 400 may be attached on the second semiconductor chip 300 for adhering the second semiconductor chip 300 to a first wafer, which will be described later. The adhesive layer 400 may be formed on the second wiring layer 320 to cover the plurality of second conductive bumps 340.

For example, the adhesive layer 400 may be formed of or include a thermosetting resin. The adhesive layer 400 may include a non-conductive film (NCF).

In some embodiments, before performing the sawing process, the adhesive layer 400 may be formed on the second wiring layer 320 of the second wafer Wa2.

Referring to FIGS. 13 to 15, a first wafer Wa1 on which a plurality of first semiconductor chips (dies) is formed may be provided.

In example embodiments, the first wafer Wa1 may include a first substrate 110 having a first surface 112 and a second surface 114 opposite to the first surface 112. The first substrate 110 may include a die region DA and a scribe lane region SA surrounding the die region DA. As will be described below, the first substrate 110 may be cut along the scribe lane region SA that divides the plurality of die regions DA of the first wafer Wa1 through a sawing process to be individualized into a plurality of first semiconductor chips.

A plurality of circuit elements may be formed on the die region DA of the first surface 112 of the first substrate 110. The first semiconductor chip may be a logic chip including a logic circuit. The logic chip may be a controller that controls memory elements of the second semiconductor chip. For example, the first semiconductor chip may be a processor chip such as an ASIC as a host such as a CPU, GPU, or SOC, or an application processor. Alternatively, the circuit element may include a plurality of memory elements. For example, the memory devices may include volatile semiconductor memory devices and non-volatile semiconductor memory devices. For example, the volatile semiconductor memory device may include DRAM, SRAM, etc. For example, the non-volatile semiconductor memory devices may include EPROM, EEPROM, and Flash EEPROM.

The circuit elements may include, for example, a transistor, a capacitor, a wiring structure, etc. The circuit elements may be formed on the first surface 112 of the first substrate 110 by performing a fab process called front-end-of-line (FEOL) for manufacturing semiconductor devices. The surface of the first substrate on which the FEOL process is performed may be referred to as the front surface of the second substrate, and a surface opposite to the front surface may be referred to as the backside surface. An insulation interlayer may be formed on the first surface 112 of the first substrate 110 to cover the plurality of circuit elements.

The first wafer Wa1 may include a first wiring layer 120 disposed on the first surface 112 of the first substrate 110, a plurality of first bonding pads 130 disposed on the first wiring layer 120, a plurality of second bonding pads 180 disposed on the second surface 114 of the first substrate 110, and a plurality of through electrodes 160 penetrating the first substrate 110 to be electrically connected to the first and second bonding pads 130 and 180, respectively.

When viewed in a plan view, the die region DA of the first wafer Wa1 may have a rectangular shape including first to fourth edges S11, S12, S13, and S14. The die region DA of the first wafer Wa1 may include a chip mounting region MR and a test region TR. The chip mounting region MR may be a rectangular shape area disposed on a center of the die region DA. The chip mounting region MR may include first to fourth edges S21, S22, S23, and S24. The plurality of second bonding pads 180 may be arranged in an array form on the chip mounting region MR. The test region TR may be an area provided on a peripheral region of the die region DA surrounding the chip mounting region MR. For example, the test region TR may be an area in the die region DA excluding the chip mounting region MR.

In example embodiments, a plurality of measurement structures 200 may be provided on the die region DA of the first wafer Wa1. The plurality of measurement structures 200 may include a plurality of first measurement structures 210 and a plurality of second measurement structures 220. The plurality of first measurement structures 210 and the plurality of second measurement structures 220 may include a plurality of metal lines having a predetermined width T1 and a predetermined height T2. For example, the predetermined width T1 and the predetermined height T2 of the plurality of first measurement structures 210 and the plurality of second measurement structures 220 may be within a range of 1 μm to 3 μm. For example, the plurality of metal lines may be formed of or include metal material such as copper (Cu).

The plurality of first measurement structures 210 and the plurality of second measurement structures 220 may be electrically connected to first redistribution wirings 123 of the first wafer Wa1 by the plurality of through electrodes 160 of the first wafer Wa1. The first redistribution wiring 123 may be electrically connected to the plurality of first bonding pads 130 that are provided on the lower surface 112 of the first substrate 110 of the first wafer Wa1.

The plurality of first measurement structures 210 and the plurality of second measurement structures 220 may be disposed on the upper surface 114 of the first substrate 110 of the first semiconductor chip 100. For example, the plurality of first measurement structures 210 and the plurality of second measurement structures 220 may be disposed on the test region TR adjacent to the edges of the chip mounting region MR of the die region DA.

The plurality of first measurement structures 210 may include a first width measurement structure 210a, a second width measurement structure 210b and a third width measurement structure 210c.

The plurality of first measurement structures 210 may be disposed on the test region TR of the die region DA. For example, the plurality of first measurement structures 210 may be sequentially arranged in a row from the first edge S21 of the chip mounting region MR toward the first edge S11 of the first semiconductor chip 100 including the die region DA. For example, the first width measurement structure 210a may be disposed on the test region TR to be spaced apart from the first edge S21 of the chip mounting region MR along the first direction (X direction) by a first distance D1 (see, e.g., FIG. 14). The second width measurement structure 210b may be disposed on the test region TR to be spaced apart from the first width measurement structure 210a in the first direction (X direction) by a second distance D2. The third width measurement structure 210c may be disposed on the test region TR to be spaced apart from the second width measurement structure 210b in the first direction (X direction) by a third distance D3. Each of the first measurement structures 210 may extend in a straight line shape in a direction parallel to the closest edge of the first semiconductor chip 100.

The plurality of first measurement structures 210 may be arranged on the test region TA of the first semiconductor chip 100 such that the plurality of first measurement structures 210 are sequentially arranged away from one of the edges of the chip mounting region MR at equal intervals. For example, the first to third width measurement structure 210a, 210b and 210c may be sequentially arranged away from the first edge S21 of the chip mounting region MR at equal intervals. The first distance D1, the second distance D2, and the third distance D3 may be the same. For example, the first distance D1, the second distance D2, and the third distance D3 may be within a range of 15 μm to 100 μm. Because the boundary in plan view of the second semiconductor chip 300 may be coextensive with the boundary of the chip mounting region MR, the plurality of first measurement structures 210 may be arranged outside the boundary of the second semiconductor chip 300 in plan view and may be sequentially arranged away from a corresponding edge of the second semiconductor chip 300 at equal intervals.

The plurality of first measurement structures 210 may be arranged to extend in a direction parallel to an extension direction of the edge of the chip mounting region MR. Additionally, the plurality of first measurement structures 210 may be arranged to extend in a direction perpendicular to the extension direction of the edge of the chip mounting region MR. For example, the first width measurement structure 210a, the second width measurement structure 210b, and the third width measurement structure 210c disposed on an area adjacent to the first edge S21 of the chip mounting region MR may extend parallel to the second direction (Y direction). Additionally, the first width measurement structure 210a, the second width measurement structure 210b, and the third width measurement structure 210c disposed on an area adjacent to the third edge S23 of the chip mounting region MR may extend in the first direction (X direction). The number and lengths of the plurality of first measurement structures 210 may be determined in consideration of the overall size of the package and the sizes of semiconductor chips included in the package.

Although only a few first measurement structures 210 are shown in the drawings, it should be understood that the number and shape of the plurality of first measurement structures 210 are illustrative, and that the present invention is not limited thereto.

The plurality of second measurement structures 220 may include a first coverage measurement structure 220a and a second coverage measurement structure 220b. The plurality of second measurement structures 220 may extend from the chip mounting region MR of the first wafer Wa1 to the test region TR of the first wafer Wa1.

The plurality of second measurement structures 220 may extend from the chip mounting region MR to the test region TR to cross a boundary portion (e.g., a boundary) between the chip mounting region MR and the test region TR. For example, the first coverage measurement structure 220a and the second coverage measurement structure 220b may be disposed between the ends of the first edge S21 of the chip mounting region MR to cross the first edge S21 of the chip mounting region MR. The first coverage measurement structure 220a may be disposed adjacent to the third edge S23 of the chip mounting region MR, and the second coverage measurement structure 220b may be disposed adjacent to the fourth edge S24 of the chip mounting region MR. For example, a distance from the first coverage measurement structure 220a to the third edge S23 may be smaller than a distance from the first measurement structures 210 to the third edge S23. For example, a distance from the second coverage measurement structure 220b to the fourth edge S24 may be smaller than a distance from the first measurement structures 210 to the fourth edge S24.

The plurality of second measurement structures 220 may be disposed adjacent to corner areas (e.g., corners) of the chip mounting region to cross the edges of the chip mounting region MR. For example, the first coverage measurement structure 220a may be disposed adjacent to a first corner where the first edge S21 and the third edge S23 meet each other to cross the first edge S21. The second coverage measurement structure 220b may be disposed adjacent to a second corner where the first edge S21 and the fourth edge S24 meet each other to cross the first edge S21.

The plurality of second measurement structures 220 may be spaced apart from the corresponding corner of the chip mounting region MR toward a center of the corresponding edge of the chip mounting region MR by a predetermined distance. For example, the first coverage measurement structure 220a may be disposed to be spaced apart from the S21-S23 corner of the chip mounting region MR by a fourth distance D4 toward the center of the first edge S21 of the chip mounting region MR. The fourth distance D4 may be within a range of 500 μm to 1500 μm.

The plurality of second measurement structures 220 may extend in a direction perpendicular to the corresponding edge of the chip mounting region MR of the first semiconductor chip 100. For example, the first coverage measurement structure 220a and the second coverage measurement structure 220b may extend in a direction perpendicular to the first edge S21 to cross the first edge S21 of the chip mounting region MR. Because the boundary in plan view of the second semiconductor chip 300 may be coextensive with the boundary of the chip mounting region MR, a portion of each second measurement structure 220 may be underneath the second semiconductor chip 300 in plan view and a remaining portion of each second measurement structure 220 may not be underneath the second semiconductor chip 300 in plan view.

The plurality of second measurement structures 220 may be disposed to be closer to the chip mounting region MR of the first semiconductor chip 100 than the plurality of first measurement structures 210.

A distance between the plurality of second measurement structures 220 may be greater than a length of each of the plurality of first measurement structures 210. For example, the distance between the first coverage measurement structure 220a and the second coverage measurement structure 220b may be a first length L1. The length of each of the first measurement structures 210 may be a second length L2. The first length L1 may be greater than the second length L2. For example, the first length L1 may be smaller than the length of the first edge S21 of the chip mounting region MR of the first semiconductor chip 100.

Referring to FIGS. 16 to 18, a second semiconductor chip 300 may be stacked on the first wafer Wa1 using a wafer support system (WSS). A plurality of second semiconductor chips may be disposed on the first wafer Wa1 to correspond to the die regions DA respectively. The second semiconductor chip 300 may be attached to the first wafer Wa1 using an adhesive layer 400. The second semiconductor chip 300 may be disposed on the first wafer Wa1 such that a first surface 312 of a second substrate 310 of the second semiconductor chip 300 faces the first wafer Wa1.

The second semiconductor chip 300 may be attached to the first wafer Wa1 by performing a thermal compression bonding process at a predetermined temperature (for example, about 400° C. or less). The thermal compression bonding process may be performed to bond the second semiconductor chip 300 and the first wafer Wa1 to each other.

In the thermal compression bonding process, a non-conductive film as the adhesive layer may change into a liquid and have a fluidity. The liquefied non-conductive film may flow between a plurality of second conductive bumps 340 disposed between the second semiconductor chip 300 and the first wafer including the first semiconductor chip 100, and then the liquefied non-conductive film may be cured to cover the second conductive bumps 340 and fill a space between the plurality of second conductive bumps 340. A portion of the cured adhesive layer 400 may protrude from side surfaces of the second semiconductor chip 300 to cover at least a portion of the test region TR of the die region DA of the first wafer Wa1.

The cured adhesive layer 400 may include a central portion 410 that fills a gap G under the second semiconductor chip 300 and a plurality of overflow portions 420 protruding from the side surfaces of the second semiconductor chip 300. The overflow portions 420 may include a first overflow portion 421 protruding from the first edge S21 of the chip mounting region MR, a second overflow portion protruding from the second edge S22 of the chip mounting region MR. 422, a third overflow portion 423 protruding from the third edge S23 of the chip mounting region MR and a fourth overflow portion 424 protruding from the fourth edge S24 of the chip mounting region MR.

The overflow portions 420 of the cured adhesive layer 400 may be in contact with at least one of the plurality of first measurement structures 210. A distance from the edge of the second semiconductor chip 300 to the farthest one of the plurality of first measurement structures 210 that are in contact with the overflow portion may be a first width W1 of the overflow portions 420 (see, e.g., FIGS. 17 and 18). For example, the first overflow portion 421 may contact the first width measurement structure 210a and the second width measurement structure 210b among the plurality of first measurement structures 210. The first width W1 of the first overflow portion 421 may be a distance from the edge of the second semiconductor chip 300 to the second width measurement structure 210b. For example, the first width W1 of the first overflow portion 421 may be a distance from the edge of the second semiconductor chip 300 to the center of the second width measurement structure 210b. However, the inventive concept is not limited thereto. For example, the first width W1 of the first overflow portion 421 may be a distance from the edge of the second semiconductor chip 300 to a far edge of the second width measurement structure 210b or to a near edge of the second width measurement structure 210b. For example, the first width W1 of the first overflow portion 421 may be the same or similar with a sum of the first distance D1, which is a distance from the first edge S21 of the chip mounting region MR to the first width measurement structure 210a, and the second distance D2, which is the distance from the first width measurement structure 210a to the second width measurement structure 210b.

The central portion 410 of the cured adhesive layer 400 may contact at least one of the plurality of second measurement structures 220. For example, the central portion 410 of the cured adhesive layer 400 may contact the first coverage measurement structure 220a and the second coverage measurement structure 220b disposed between ends of the first edge S21 of the chip mounting region MR. A width of the central portion 410 adjacent to the first edge S21, in the direction of the first edge S21, may be a second width W2. The second width W2 may be equal to or similar to the first length L1 between the first coverage measurement structure 220a and the second coverage measurement structure 220b.

The thermal compression bonding process may be performed to bond the plurality of second conductive bumps 340 of the second semiconductor chip 300 to the plurality of second bonding pads 180 of the first wafer, respectively. The plurality of second bonding pads 180 may be electrically connected to the plurality of first bonding pads 130 through the plurality of through electrodes 160, the first redistribution wirings 123 of the first wiring layer 120 and the plurality of redistribution pads 125.

Referring to FIGS. 19 to 21, a molding member may be formed on the first wafer Wa1 to cover the second semiconductor chip 300. And then, a cure process may be performed to harden the molding member 500.

In example embodiments, the molding member 500 may be disposed on the first wafer Wa1 to fill spaces between the plurality of second semiconductor chips 300. The molding member 500 may cover side surfaces of the plurality of second semiconductor chips 300. An upper surface, that is, a backside surface, of the second semiconductor chip 300 may be exposed from the molding member 500. For example, the molding member 500 may be formed of or include a thermosetting resin.

The molding member 500 may include a plurality of points where the measurement structures 200 and the adhesive layer 400 are in contact simultaneously. For example, the molding member 500 may include a first point P1 and a second point P2 that are points at which the second width measurement structure 210b and the first overflow portion 421 are in contact simultaneously with the molding member 500.

The curing process may be performed to harden the molding member 500 by applying high temperature and pressure to the first wafer Wa1 filled with the molding member 500.

At the points where the molding member 500, the adhesive layer 400, and the measurement structures 200 are in contact simultaneously, an accumulated stress may occur because of difference of coefficient of thermal expansion (CTE) between the molding member 500, the adhesive layer 400 and the measurement structures 200. Accordingly, cracks may occur in the measurement structures 200 at the above points. For example, a crack of the second width measurement structure 210b may occur at the first point P1 and the second point P2, which are points where the molding member 500, the second width measurement structure 210b and the first overflow portion 421 are in contact with each other simultaneously.

Referring to FIG. 22, the plurality of first conductive bumps 140 may be formed on the plurality of first bonding pads 130 of the first wafer Wa1, and then an EDS (Electrical Die Sorting) process may be performed on the first wafer Wa1 to proactively select defective packages. The EDS process may be a process of selecting products which do not have any defects by checking a condition of each chip (die) through an inspection of various electrical characteristics of the wafer. During the EDS process, fine pins of a probe card may contact the plurality of first conductive bumps 140 provided on a lower surface of the first wafer Wa1 to transmit test signals and detect electrical signals.

By performing the EDS process, a portion of the measurement structures 200 in which cracks occur during the curing process may be selected. The measurement structures 200 may be electrically connected to the through electrode 160, the first redistribution wiring 123 and the redistribution pad 125 of the first wafer Wa1, respectively. The redistribution pads 125 may be electrically connected to the corresponding first bonding pads 130 and first conductive bumps 140, respectively. Accordingly, changes in resistance values due to cracks in the measurement structures 200 may be measured through conductive structures connected to the measurement structures 200. For example, in the case that cracks occur in some of the measurement structures 200, the corresponding resistance value may rapidly increase when performing the EDS process. Electrical signals of the measurement structures 200 may be transmitted through the plurality of through electrodes 160, the first redistribution wiring 123, the redistribution pad 125 and the first bonding pads 130 and the first conductive bumps 140, respectively. Accordingly, the rapidly increased resistance value may be measured by contacting the first conductive bumps 140 corresponding to the cracked measurement structures 200.

A size of the cured adhesive layer 400 may be measured by determining in which of the measurement structures 200 the cracks have occurred.

The overflow portions 420 of the cured adhesive layer 400 may contact a portion of the plurality of first measurement structures 210. As described above, cracks may occur in the first measurement structures 210 at a point where the overflow portions 420 of the cured adhesive layer 400 contact the plurality of first measurement structures 210 and the molding member 500 at the same time. The EDS process may be performed to select the portions of the plurality of first measurement structures 210 in which the cracks occur, and then the first width (W1, see FIG. 17) of the overflow portions 420 of the cured adhesive layer 400 may be measured.

The central portion 410 of the cured adhesive layer 400 may contact a portion of the plurality of second measurement structures 220. As described above, cracks may occur at a point where the central portion 410 of the cured adhesive layer 400 is in contact with the plurality of second measurement structures 220 and the molding member 500 at the same time. The EDS process may be performed to select the portions of the plurality of second measurement structures 220 in which the cracks occurred, and then the second width (W2, see FIG. 17) of the central portion 410 of the cured adhesive layer 400 may be measured.

By measuring the size of the cured adhesive layer 400, defective packages may be proactively selected. For example, a defective package may be determined as having a first width W1 and/or a second width W2 above or below a predetermined threshold value, or as having a first width W1 and/or a second width W2 within or outside of a predetermined threshold range of values.

For example, in the case that the first width W1 of the overflow portions 420 of the cured adhesive layer 400 may be larger than the expected width, the non-conductive film may be exposed outside the chip. Accordingly, defective products may occur that reduce a reliability of a final product.

For example, in the case that the second width W2 of the central portion 410 of the cured adhesive layer 400 may be smaller than the expected width, the non-conductive film may not sufficiently cover the lower surface of the second semiconductor chip 300. Accordingly, defective products may occur that reduce a reliability of a final product.

The defective products may be proactively selected by measuring the cracks of the measurement structures 200 without an additional defective product selection process. Therefore, the time and cost consumed for the additional defective product selection process may be reduced.

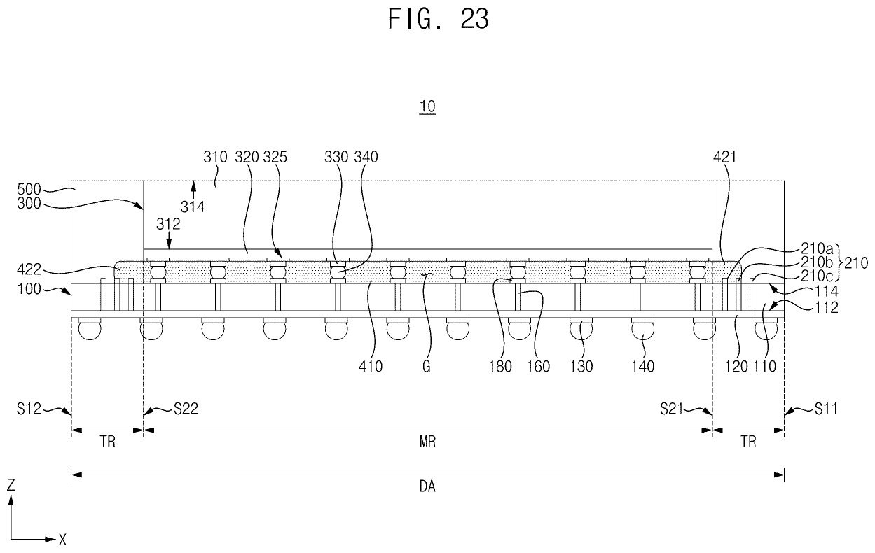

Referring to FIG. 23, the first wafer Wa1 and the molding member 500 may be cut along the scribe lane region SA to form an individualized first semiconductor chip 100. The first wafer Wa1 may be cut through a sawing process. Thus, a semiconductor package as a stack package 10 including the second semiconductor chip 300 stacked on the first semiconductor chip 100 may be formed.

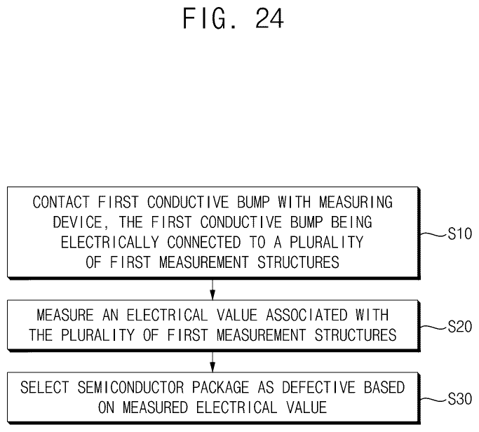

FIG. 24 shows a method of selective a defective semiconductor package according to an embodiment.

Referring to FIG. 24, in step S10, a first conductive bump is contacted with a measuring device. The first conductive bump is electrically connected to a plurality of first measurement structures positioned on a test region of a first semiconductor chip of a semiconductor package.

In step S20, an electrical value associated with the plurality of first measurement structures is measured using the measuring device.

In step S30, the semiconductor package is selected as defective based on the measured electrical value.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

1. A semiconductor package, comprising:
a first semiconductor chip having a chip mounting region on a central portion of an upper surface of the first semiconductor chip and a test region surrounding the chip mounting region;
a plurality of first measurement structures on the test region and sequentially arranged in a direction perpendicular to an edge of the chip mounting region to be spaced apart from the edge of the chip mounting region;
a second semiconductor chip mounted on the chip mounting region of the first semiconductor chip via a plurality of conductive bumps;
an adhesive layer filling a gap between the first semiconductor chip and the second semiconductor chip, and the adhesive layer including a central portion on the chip mounting region and at least one overflow portion protruding from the central portion to the test region to contact at least one of the plurality of first measurement structures; and
a molding member on the upper surface of the first semiconductor chip to cover side surfaces of the second semiconductor chip.

2. The semiconductor package of claim 1, wherein each of the plurality of first measurement structures extends in a second direction perpendicular to a first direction in which the edge of the chip mounting region extends.

3. The semiconductor package of claim 1, wherein the adhesive layer includes a non-conductive film (NCF).

4. The semiconductor package of claim 1, wherein each of the plurality of first measurement structures comprises a metal line including copper (Cu).

5. The semiconductor package of claim 1, further comprising:
a plurality of second measurement structures extending from the chip mounting region to the test region.

6. The semiconductor package of claim 5, wherein the central portion of the adhesive layer is in contact with at least one of the plurality of second measurement structures.

7. The semiconductor package of claim 5, wherein each of the plurality of second measurement structures comprises a metal line including copper (Cu).

8. The semiconductor package of claim 1, wherein the first semiconductor chip includes:
a first substrate;
a plurality of through electrodes penetrating the first substrate;
a first wiring layer on a first surface of the first substrate, the first wiring layer having a plurality of redistribution pads; and
a plurality of first bonding pads respectively disposed on the plurality of redistribution pads.

9. The semiconductor package of claim 8, wherein the plurality of first measurement structures are electrically connected to the plurality of first bonding pads via at least one of the plurality of through electrodes of the first semiconductor chip and via the first wiring layer.

10. The semiconductor package of claim 8, wherein the first semiconductor chip has a second surface opposite to the first surface, wherein the first semiconductor chip has a plurality of second bonding pads on the second surface, and
the plurality of conductive bumps are respectively disposed on the plurality of second bonding pads.

11. A semiconductor package, comprising:
a first semiconductor chip having a chip mounting region on a central portion of an upper surface of the first semiconductor chip and a test region surrounding the chip mounting region;
a plurality of first measurement structures on the test region and sequentially arranged to be spaced apart from an edge of the chip mounting region;
a plurality of second measurement structures extending from the chip mounting region to the test region;
a second semiconductor chip mounted on the chip mounting region of the first semiconductor chip via a plurality of conductive bumps;
an adhesive layer filling a gap between the first semiconductor chip and the second semiconductor chip, and the adhesive layer including a central portion on the chip mounting region to contact at least one of the plurality of second measurement structures and at least one overflow portion protruding from the central portion to the test region to contact at least one of the plurality of first measurement structures; and
a molding member on the upper surface of the first semiconductor chip to cover side surfaces of the second semiconductor chip.

12. The semiconductor package of claim 11, wherein each of the plurality of first measurement structures extends in a second direction perpendicular to a first direction in which the edge of the chip mounting region extends.

13. The semiconductor package of claim 11, wherein the adhesive layer includes a non-conductive film (NCF).

14. The semiconductor package of claim 11, wherein each of the plurality of first measurement structures and each of the plurality of second measurement structures comprises a metal line including copper (Cu).

15. The semiconductor package of claim 11, wherein the first semiconductor chip includes:
a first substrate;
a first wiring layer on a first surface of the first substrate, the first wiring layer having a plurality of redistribution pads;
a plurality of through electrodes penetrating the first substrate; and
a plurality of first bonding pads respectively disposed on the plurality of redistribution pads, and
wherein the plurality of first measurement structures and the plurality of second measurement structures are electrically connected to the plurality of first bonding pads via at least one of the plurality of through electrodes of the first semiconductor chip and via the first wiring layer.

16. The semiconductor package of claim 15, wherein the first semiconductor chip includes a plurality of second conductive bumps respectively disposed on the plurality of first bonding pads.

17. The semiconductor package of claim 15, wherein the first semiconductor chip has a second surface opposite to the first surface, the first semiconductor chip having a plurality of second bonding pads on the second surface,
wherein the second semiconductor chip has a plurality of third bonding pads on a surface of the second semiconductor chip,
wherein the plurality of conductive bumps are respectively disposed between the plurality of second bonding pads and the plurality of third bonding pads.

18. A semiconductor package, comprising:
a first semiconductor chip including:
a first substrate,
a plurality of through electrodes penetrating the first substrate,
a first wiring layer on a first surface of the first substrate, the first wiring layer having a plurality of first redistribution pads,
a plurality of first bonding pads respectively disposed on the plurality of first redistribution pads, and
a plurality of second bonding pads respectively disposed on a chip mounting region of a second surface opposite to the first surface of the first substrate;
a second semiconductor chip including:
a second substrate,
a second wiring layer on a first surface of the second substrate, the second wiring layer having a plurality of second redistribution pads, and
a plurality of third bonding pads respectively disposed on the plurality of second redistribution pads, the second semiconductor chip being mounted on the chip mounting region of the first semiconductor chip via a plurality of conductive bumps respectively disposed between the plurality of second bonding pads and the plurality of third bonding pads;
a plurality of first measurement structures on the second surface of the first semiconductor chip parallel to edges of the chip mounting region, the plurality of first measurement structures being sequentially arranged to be spaced apart by a constant distance along a direction from an edge of the chip mounting region toward an edge of the first semiconductor chip that faces the edge of the chip mounting region,
a plurality of second measurement structures respectively disposed between ends of each edge of the chip mounting region to extend along a direction perpendicular to each edge of the chip mounting region;
an adhesive layer filling a gap between the first semiconductor chip and the second semiconductor chip, the adhesive layer including a central portion on the chip mounting region to contact at least one of the plurality of second measurement structures and at least one overflow portion protruding from the chip mounting region to a test region surrounding the chip mounting region to contact at least one of the plurality of first measurement structures; and
a molding member on the second surface of the first semiconductor chip to cover side surfaces of the second semiconductor chip.

19. The semiconductor package of claim 18, wherein the adhesive layer includes a non-conductive film (NCF).

20. The semiconductor package of claim 18, wherein the plurality of first measurement structures and the plurality of second measurement structures are electrically connected to the plurality of first bonding pads via at least one of the plurality of through electrodes of the first semiconductor chip and via the first wiring layer.

21-26. (canceled)
